(19) United States
(12) Patent Application Publication
(10) Pub. No.: US 2025/0093448 A1
(43) Pub. Date: Mar. 20, 2025

(54) ARTIFICIAL INTELLIGENCE-BASED MAGNETIC RESONANCE SEQUENCE

(71) Applicant: Siemens Healthineers AG, Forchheim (DE)

(72) Inventors: Simon Arberet, Princeton, NJ (US); Dorin Comaniciu, Princeton, NJ (US)

(21) Appl. No.: 18/468,756

(22) Filed: Sep. 18, 2023

(51) Int. Cl. G01R 33/54; G06N 3/092

(52) U.S. Cl. CPC G01R 33/546; G06N 3/092

(57) ABSTRACT

For artificial Intelligence-based optimization of a MR sequence, an agent machine trained with reinforcement learning generates the MR pulse sequence for a patient. The agent may generate values for multiple or all the parameters defining the MR pulse sequence. The agent was trained using the end goal or task (e.g., MR map or segmentation) as the reward function, so the MR pulse sequence generated by the agent provides good quality MR imaging. The agent generates the MR pulse sequence quickly and without requiring multiple sequences to be used on the patient.

### BACKGROUND

Magnetic resonance imaging (MRI) scanners are complex machines that require specific MR pulse sequences to scan a patient to generate images. Practitioners use various sequences, including spin-echo, fast spin-echo, inversion recovery, short tau inversion recovery, fluid-attenuated inversion recovery, gradient echo sequences, steady-state free precession, and others. Each sequence includes many options. These sequences are determined through empirical methods, with practitioners conducting trial and error experiments to optimize parameters such as echo time, repetition time, echo train length, or flip angle to achieve the desired contrast and reduce artifacts. It can be difficult to achieve good quality. Multiple MRI scans are often required to compensate for the suboptimal quality of each individual scan, resulting in lengthy examination times. The use of multiple sequences during an examination is time-consuming, expensive, and increases the workload of radiologists who must analyze all the resulting images. Although artificial intelligence (AI) has allowed for MR reconstruction with higher acceleration, reducing overall examination time, MRI sequences are still typically designed manually.

### SUMMARY

By way of introduction, the preferred embodiments described below include methods, systems, instructions, and non-transitory computer readable media for artificial Intelligence-based optimization of a MR sequence. An agent machine trained with reinforcement learning generates the MR pulse sequence for a patient. The agent may generate values for multiple or all the parameters defining the MR pulse sequence. The agent was trained using the end goal or task (e.g., MR map or segmentation) as the reward function, so the MR pulse sequence generated by the agent provides good quality MR imaging. The agent generates the MR pulse sequence quickly and without requiring multiple sequences to be used on the patient.

In a first aspect, a method of establishing the MR pulse sequence is provided for a MR scanner. Indications of an environment for MR scanning of a patient are received. A reinforcement learned AI establishes the MR pulse sequence for the environment based on input of the environment and a digital twin of the patient. The reinforcement learned AI establishes the MR pulse sequence in the environment for the digital twin of the patient by optimization. The MR scanner is configured with the MR pulse sequence, and the MR scanner as configured images with the MR pulse sequence.

In a second aspect, a method is provided for reinforcement machine learning to establish a MR pulse sequence. A state space representing the MR pulse sequence, a MR scanner, and a virtual object to be scanned is defined. An action space of the MR pulse sequence is parameterized with a plurality of objects corresponding to actions changing a characteristic of the MR pulse sequence. A processor performed reinforcement learning of an agent. The reinforcement learning simulates different MR pulse sequences, different MR scanners, and different virtual objects of the state space in different combinations where each combination is optimized in the action space. The agent is stored.

In a third aspect, a magnetic resonance (MR) system includes a MR scanner configured by settings of controls to scan a region of a patient. A processor is configured by a machine-learned agent to configure the MR scanner. The machine-learned agent uses simulation of MR scanning by the MR scanner with different values of the settings through a sequence of simulated actions. The different values are optimized by the machine-learned agent where the optimized values are used for the settings of the configuration of the MR scanner.

Other aspects are summarized below in the illustrative embodiments. Aspects noted for one type of illustrative embodiment (method or system) may be used in another type. The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

FIG. 1 is a block diagram of an embodiment of an MR system for MR imaging with a pulse sequence established by artificial intelligence;

FIG. 2 is a flow chart diagram of one embodiment of a method for reinforcement machine learning for MR pulses sequence generation;

FIG. 3 illustrates reinforcement machine learning in an MR environment;

FIG. 4 illustrates simulation for reinforcement training an agent with an end task of map generation;

FIG. 5 illustrates simulation for reinforcement training an agent with an end task of annotation (e.g., segmentation); and

FIG. 6 is a flow chart diagram of one embodiment of a method for establishing, by artificial intelligence, a MR pulse sequence for a MR scanner

### DETAILED DESCRIPTION

Some attempts have been made to optimize MRI pulse sequences. Two approaches have been used: maximizing the Fisher information, i.e. minimizing the Cramer-Rao bound, and minimizing the correlation of the Bloch magnetization responses of different tissue parameters (T1, T2). These approaches are limited to optimizing only one or two parameters, such as flip angle or repetition time, using local criteria. These approaches do not capture the end goal of the MRI sequence. Additionally, the approaches ignore the effects of sampling patterns, which can generate artifacts with more consequential effects than the Gaussian noise assumed in these models. Sequences optimized using these criteria have improved the targeted criterion but have ultimately worsened reconstruction results. The presence of multiple local minima in the optimization problem leads to suboptimal solutions that are near the initial solution when using gradient-based optimization.

Rather than optimizing the MR pulse sequence, sampling patterns of the already acquired scan data are optimized in another approach. The MR pulse sequence is not optimized. A fully sampled acquisition is used, and the k-space data is retrospectively downsampled to simulate different sampling patterns. The loss is back propagated to the sampling pattern parameters in an end-to-end fashion. This framework cannot be extended to change other parameters of the MRI sequence, as alterion of other parameters would change the contrast of the target and require a new acquisition of the data to generate ground truth. It is also expected that the gradient information cannot be used to optimize most of the sequence parameters because of non-differentialbility issues. This approach is limited to sequences where a fully sampled acquisition is possible, which is not feasible for many types of sequences such as HASTE, MRF, DWI EPI, and GRASP.

To overcome the limitations of the above approaches, a reinforcement learning (RL) agent is trained to optimize the parameters of MRI sequences. The RL agent is trained to optimize MRI sequences for different scanners with varying specifications and a dataset of different objects with various body regions, with the goal of solving specific tasks such as image reconstruction for different tissue maps, organ segmentation, or tumor detection, while minimizing acquisition time. Large-scale cluster computation and AI are leveraged to find optimal MR sequences that can achieve the desired imaging goals while minimizing both the number of scans and the acquisition time required in the MR scanner. The time and cost of the examination is reduced while improving efficiency and accuracy.

In one implementation, all the parameters of the MR pulse sequence may be optimized, including the sampling pattern and other parameters, leading to more optimal MR pulse sequences. In another implementation, the reward (loss function) used in the reinforcement learning is global as the reward is based on the end task as opposed to a local heuristic. As a consequence, the effects of the different sampling patterns artifacts, coil sensitivities, spectral noise, or other imperfections or features of the system, or the reconstruction and segmentation algorithms are taken into account. The sequence is adapted to the end goal. The AI-based RL approach is used for the optimization as opposed to gradient based optimizations. These gradient based approaches are limited to continuous optimizations which only converge to local minimas, i.e. often close to the initial condition. The RL approach is better adapted to this kind of optimization problem.

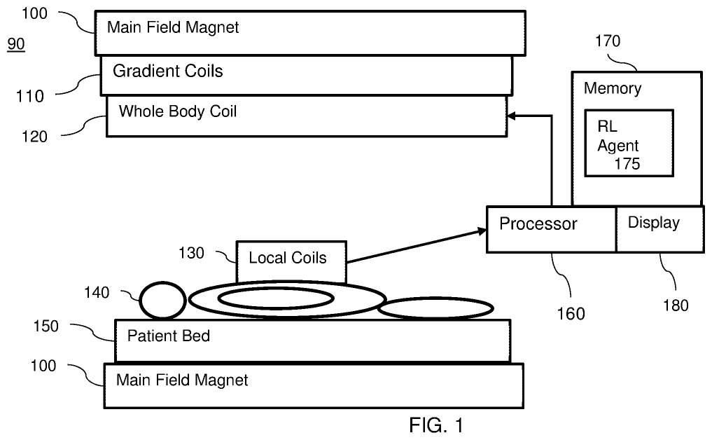

FIG. 1 shows one embodiment of a MR system for MR scanning by an MR scanner 90. A processor 160 configures the MR scanner 90 for scanning. A RL agent implemented by the processor 160 optimizes the MR pulse sequence for the MR scanner 90 to scan a patient 140. Multiple different parameters may be optimized for the MR imaging environment for a particular patient. Since the RL agent was trained with the end task (e.g., map (e.g., image) and/or annotation (e.g., segmentation or detection) being used for the reward, the resulting end task for the MR imaging with the MR pulse sequence may be better for that end task (e.g., fewer artifacts and/or limiting rescanning). The MR system performs the acts of FIG. 5 or another method. The MR scanner 90 scans the given patient 140 using the optimized MR pulse sequence created by the agent.

The MR scanner 90 includes a main field magnet 100, gradient coils 110, whole body coil 120, local coils 130, and a patient support (e.g., bed) 150. The MR system includes the MR scanner 90, processor 160, memory 170, and display 180. Additional, different, or fewer components may be provided for the MR scanner 90 and/or MR system. For example, the local coils 130 or the whole-body coil 120 are not used. In another example, the processor 160, memory 170, and display 180 are provided without the coils 100-120 and patient support 150, such as a workstation that communicates with one or more MR scanners 90. In yet another example, the processor 160, memory 170, and/or display 180 are part of the MR scanner 90.

The MR scanner 90 is configured by settings of controls to scan a region of the patient 140. The values of the settings configure the MR scanner 90 to scan the patient. The settings define the MR pulse sequence for transmission of pulses and/or measurement of response. The scan provides scan data in a scan domain. The MR scanner 90 scans the patient 140 to provide raw measurements. For the scan, the main field magnet 100 creates a static base magnetic field, BO, in the body of the patient 140 positioned on the patient support 150. The gradient coils 110 produce position dependent magnetic field gradients superimposed on the static magnetic field. The gradient coils 110 produce position dependent and shimmed magnetic field gradients in three orthogonal directions and generate magnetic field pulse sequences. The whole-body coil 120 and/or the local coils 130 receive radio frequency (RF) transmit pulses, producing magnetic field pulses (B1) that rotate the spins of the protons in the imaged region of the patient 140. The MR pulse sequence includes the gradient field pulses and/or the RF transmit pulses.

In response to applied RF pulse signals, the whole-body coil 120 and/or local coils 130 receive MR signals, i.e., signals from the excited protons within the body as the protons return to an equilibrium position established by the static and gradient magnetic fields. The MR signals are detected and processed by a detector, providing an MR dataset of raw data (e.g., k-space data). A raw storage array of the memory 170 stores corresponding individual measurements forming the MR dataset.

The MR scanner 90 is configured by the processor 160 to scan. Any of various scanner controls may be set, such as k-space coordinates, TR, TE, flip angle, pulse envelopes, carrier frequencies, timings, durations, and/or raw transmit pulses. A protocol, with or without user input or alteration, may establish the settings, at least initially, to be used for a particular scan. Any level of generality may be provided for the settings, such as an abstraction of the actual variables used for specific hardware or the actual variables. The memory 170 stores the configuration (e.g., a predetermined MR pulse sequence of an imaging) and the resulting raw data or measurements.

The patient support 150 is a flat or contoured slab (e.g., bed) on which the patient 140 lies or is supported. In an open bore, the patient support 150 may be formed as a recliner or chair given a larger bore.

The processor 160 configures the MR scanner 90 and/or determines values for one or more (e.g., multiple or all) settings for the MR pulse sequence. The processor 160 is a general processor, digital signal processor, graphics processing unit, application specific integrated circuit, field programmable gate array, artificial intelligence processor, tensor processor, digital circuit, analog circuit, combinations thereof, or another now known or later developed device for applying AI. The processor 160 is a single device, a plurality of devices, or a network. For more than one device, parallel or sequential division of processing may be used. Different devices making up the image processor 160 may perform different functions, such as optimizing the MR pulse sequence by one device and configuring the MR scanner 90 to scan by another device. In one embodiment, the processor 160 is a control processor or other processor of the MR scanner 90. Other processors of the MR scanner 90 or external to the MR scanner 90 may be used. In another embodiment, a server, workstation, or computer implements the processor 160.

The processor 160 is configured by software, firmware, and/or hardware to perform its tasks. The processor 160 operates pursuant to instructions stored on a non-transitory medium (e.g., memory 170) to perform various acts described herein. For AI, the processor 160 operates pursuant to an architecture and values of learnable parameters learned during machine training.

The processor 160 is configured by a machine-learned agent to configure the MR scanner 90. The different values of the MR pulse sequence are optimized by the machine-learned agent 175 by a sequence of actions taken by the agent to establish the MR pulse sequence best or sufficient for the environment. For example, the machine-learned agent uses simulation of MR scanning by the MR scanner 90 with different values of the settings through a sequence of simulated actions. A digital twin or other virtual representation of the patient is used in the simulation. The optimized values are used for the settings of the configuration of the MR scanner 90. In one implementation, the machine-learned agent 175 is configured by past training and/or user selection to establish the values of multiple ones of the settings in the optimization. In another implementation, the past RL training of the agent 175 and/or the simulation causes the optimization to be based on an end task of MR map generation and/or annotation (e.g., segmentation, detection, identification, classification, and/or diagnosis).

The reinforcement machine-learned agent 175 may be a neural network that accepts input of the environment (e.g., patient, MR scanner, and/or other state information) and outputs the MR pulse sequence (e.g., values of parameters of the MR pulse sequence). The reinforcement machine-learned agent 175 is trained to control or act to establish the MR pulse sequence. Different actions (e.g., change values of parameters of the MR pulse sequence) are performed by the agent 175 (e.g., a reinforcement deep learned network or machine-trained actor) to find a combination of values for the settings to scan this patient by this MR scanner 90. The agent may use simulation to determine the actions or provides the actions without simulation.

The machine learned agent 175 is trained by training data with ground truth. A loss based on output of the simulation compared to ground truth for one or more end tasks is used in an optimization to train the agent 175. Any optimization may be used, such as Adam. Any loss may be used, such as cross entropy, L1 loss, or L2 loss. Pre-training, cross-training, and/or continuous training may be used. The training data is gathered from a database of examples performed under expert control and/or based on simulation. Ground truth may be curated, created by expert review, or based on simulation.

The memory 170 is a cache, buffer, RAM, removable media, hard drive, or another computer readable storage medium. Non-transitory computer readable storage media include various types of volatile and nonvolatile storage media.

The memory 170 stores the settings for the controls (e.g., values of settings for the MR pulse sequence), the machine-learned agent 175, scan data, simulation data, and/or outputs (e.g., MR map and/or annotations). The memory 170 may alternatively or additionally store instructions for the processor 160. The functions, acts or tasks illustrated in the figures or described herein are executed by the processor 160 in response to one or more sets of instructions stored in or on the non-transitory computer readable storage media of the memory 170. The functions, acts, or tasks are independent of the particular type of instructions set, storage media, processor or processing strategy and may be performed by software, hardware, integrated circuits, firmware, micro code and the like, operating alone or in combination.

In one embodiment, the instructions are stored on a removable media device for reading by local or remote systems. In other embodiments, the instructions are stored in a remote location for transfer through a computer network. In yet other embodiments, the instructions are stored within a given computer, CPU, GPU, or system. Because some of the constituent system components and method steps depicted in the accompanying figures may be implemented in software, the actual connections between the system components (or the process steps) may differ depending upon the manner in which the present embodiments are programmed.

The display 180 is a CRT, LCD, plasma, projector, printer, or other display device. The display 180 is configured by loading an image to a display plane or buffer. The display 180 is configured to display the settings for the MR pulse sequence, the MR pulse sequence, and/or output of the MR scanner 90 (e.g., MR map and/or annotation).

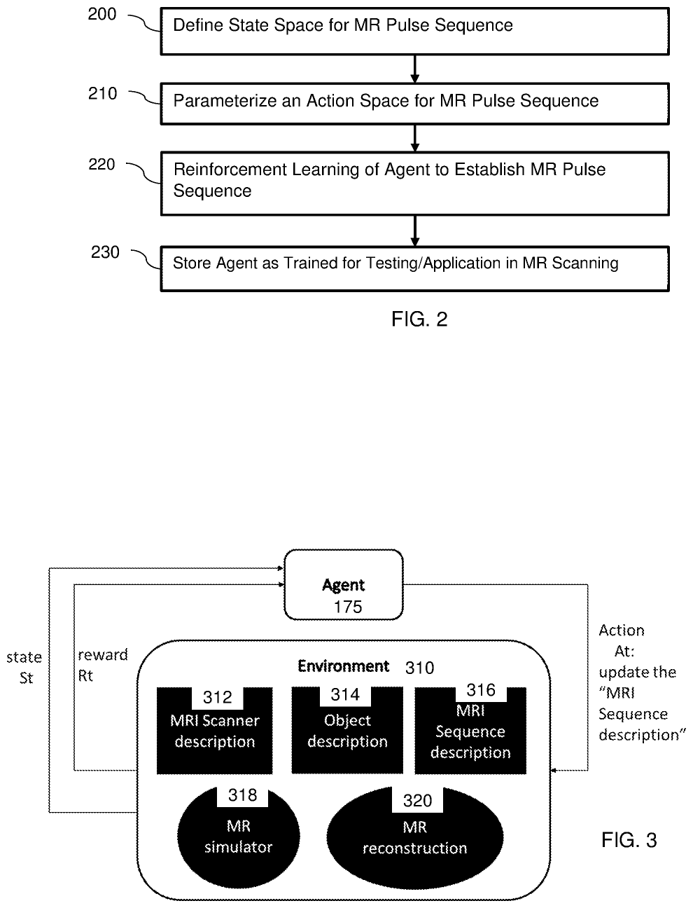

FIG. 2 illustrates one embodiment of a method for reinforcement machine learning to establish a MR pulse sequence. Deep reinforcement learning trains an agent (e.g., neural network) to implement a policy for determining actions in setting the MR pulse sequence. The agent may be trained to set multiple or all settings defining the MR pulse sequence for a given situation. The agent may be trained with rewards based on an end task (e.g., reconstructed map or segmentation).

The method of FIG. 2 is performed by the system of FIG. 1 or another system. For example, an image processor simulates MR scanning and reconstruction in different environments as part of reinforcement training of the agent to establish the MR pulse sequences optimized for the environments through a sequence of actions taken based on the policy. A memory stores the resulting network (i.e., RL trained agent) in act 230.

The acts are performed in the order shown (numerical or top-to-bottom) or other orders. For example, acts 200 and 210 are performed in the order shown, opposite order, or reverse order. Additional, different, or fewer acts may be used. For example, acts for scanning, for establishing an architecture of the machine learning network, and/or for selecting input metrics for reinforcement learning are provided. As another example, the acts for defining (act 200) and/or parameterizing (act 210) are not performed, such as where an existing environment and/or parameterization is used.

The defining of act 200 and parameterization of act 210 provide an action space of the agent and the state of the agent. Simulation is used to provide a reward function employed to train the RL agent to optimize the MR sequence.

In act 200, the processor, based on user input and/or programming, defines a state space representing the MR pulse sequence, a MR scanner, and a virtual object to be scanned. During the deployment or testing phase, the user will provide specific details of the instance of that actual environment, such as providing the scanner model, the object or type of object to scan, the body region, orientation, size, and/or end task (e.g., T1 and/or T2 maps reconstruction or organ segmentation). The user will also specify the sequence parameters they wish to optimize, which may include all the sequence parameters. This information provides the state space. For training, various instances (states) of these inputs are used with simulation.

In one implementation, the state representation includes several components: (1) a current sequence description, (2) hardware specifications of the scanner such as B0, maximum gradient Gmax, and slew rate Smax, (3) information about a virtual object (e.g., many samples of digital twins of patients or phantoms), such as proton density M0, T1, T2, T2*, off-resonance, and/or non-rigid motion field, (4) a current prediction, i.e. current image reconstruction and/or annotation output, (5) the target which can be extracted from the virtual object if it is one or multiple tissue maps, and/or annotation (e.g., segmentation which can be automatic or manual) of the organs, and/or (6) a constraint mask, which indicates parameters being optimized and parameter not being optimized, constraints (limits) to the settings, and/or filtering of the actions. The constraint mask may assist in developing the agent to optimize any subset of the action space.

Other state spaces may be created, such as the MR scanner information, patient information, and MR pulse sequence information. FIG. 3 shows an example. The environment 310 includes an MRI scanner description 312, an object description 314 (e.g., virtual patient), and an MRI pulse sequence description 316. The environment 310 also includes an MR simulator 318 to simulate the MRI scanner as described 312 scanning the object as described 314 using the MRI sequence as described 316. The environment 310 includes the MR reconstruction 320 to use for generating the output from the MR simulator 318. This environment 310 provides the state St and reward Rt to the agent 175, and the agent 175 outputs an action changing or updating the MRI sequence description 316. Through reinforcement machine training using many samples, the agent 175 (e.g., neural network with various learnable parameters) is trained to establish or optimize the MR pulse sequence through actions in various environments 310.

In act 210 of FIG. 2, the processor, based on user input and/or programming, parameterizes an action space of the MR pulse sequence. The parameterization defines the variables used to create or establish the MR pulse sequence. Any level of abstraction may be used for the parameterization. For example, the settings used by a user of the MR scanner are used, such as flip angle and repetition time. As another example, the variables for settings of circuits, processing, and/or hardware at a hardware level of the MR scanner are used, such as analog-to-digital sample rate and amplifier magnitude. In yet another example, a level of abstraction between user settings and hardware settings is used, such as variables defining different characteristics or aspects of the MR pulse sequence.

The parameterization of the action space provides the agent with settings and corresponding values defining the MR pulse sequence that can be changed as an action. The parameterization defines the acts that may be taken by the agent in the environment to optimize the MR pulse sequence.

Any format for the parameterization may be used, such as a spreadsheet or data table. A hierarchal data structure may be used, such as objects (e.g., characteristics) with nested or sub-object variables for different settings associated with the objects. In one implementation, the parameterization provides a plurality of objects corresponding to actions changing a characteristic of the MR pulse sequence.

An example parameterization defines the various actions as a sequence with each act in the sequence associated with an object (i.e., a sequence of changes to objects). Sequence objects define the action to take on the object. The sequence objects may refer to objects, such as: a block, a RF event, a gradient event, an analog-to-digital conversion (ADC) event, a shape (e.g., pulse shape), and/or a delay (e.g., of a pulse from a start time). These sequence objects have a type (Block, RF event, Gradient event, ADC event, Shape, or Delay) and an identification number (ID) used to refer to the objects in the sequence description. In each of these eight types of actions, there are two or three sequential steps labeled by the letters (a,b,c). An example is provided as:
1) Create a new object
   a. Specify the type of object among: block, RF event, Gradient event, ADC event, Shape, Delay
   b. Specify the ID number of the object preceding the newly created object
2) Delete an existing object
   a. Specify the type of object among: block, RF event, Gradient event, ADC event, Shape, Delay
   b. Specify the ID number of the object to be deleted
3) Modify a block
   a. Specify the block index
   b. Specify the tag to be modified among 6: <duration> <rf> <gx> <gy> <gz> <adc>, where <duration> is the duration of the current block, <rf> is the ID of the RF event, <gx>is the ID of the gradient event on the X channel, <gy> is the ID of the gradient event on the Y channel, <gz> is ID of the gradient event on the Z channel, <adc> is ID of the ADC event.
   c. Apply a delta change on the selected event (e.g. +/−1)
4) Modify an RF event
   a. Select the ID of the event
   b. Specify one of the RF parameters (tag): <amp> <mag id> <phase id> <time id> <delay> <freq> <phase> , with <amp> being the Peak amplitude, <mag_id> the Shape ID for magnitude profile, <phase_id> the Shape ID for phase profile, <time_id> the Shape ID for the time sampling points, <delay> being the Delay before starting the RF pulse, <freq> being the Frequency offset, and <phase> being the Phase offset.
   c. Apply a delta change on the selected event (e.g. +/−1 depending of the unit).
5) Modify a Gradient event
   a. Select the ID of the event
   b. Specify one of the Gradient parameters: <amp> <rise> <flat> <fall> <delay> , where
   c. <amp> being the Peak amplitude, <shape_id> the Shape ID for arbitrary gradient waveform, <time_id> the Shape ID for the time sampling points, <rise> the Rise time of the trapezoid, <flat> being the Flat-top time of the trapezoid, <fall> being the Fall time of the trapezoid, and <delay> being the Delay before starting the gradient event.
   d. Apply a delta change on the selected event (e.g. +/−1 depending of the unit).
6) Modify an ADC event
   a. Select the ID of the event
   b. Specify one of the ADC parameters: <num> <dwell> <delay> <freq> <phase> , where <num> being the Number of samples, <dwell> the ADC dwell time, <delay> the Delay between start of block and first sample, <freq> the Frequency offset of ADC receiver, <phase> being Phase offset of ADC receiver.
   c. Apply a delta change on the selected event (e.g. +/−1 depending of the unit).
7) Modify a Shape
   In a first embodiment, a pre-computed dictionary of shapes is utilized, which doesn't require any modifications to the shapes themselves. Instead, a shape's ID is used to specify which shape should be used in a given block.
   In a second embodiment, each sample of every shape is customized. In this scenario, the following actions can be performed:
   a. Select the ID of the shape.
   b. Select the ID of the sample in that shape
   c. Apply a delta change on the selected event (e.g. +/−1).
8) Modify a delay event
   a. Select the ID of the event
   b. Apply a delta change on the selected event (e.g. +/−1).
      Other combinations or sets of acts may be provided, such as using sequence objects (e.g., actions) 1-6 and 8 but not 7 in the example above. Other actions, objects, and/or sub-objects may be provided.

To represent the action space, one approach is to start with an ID dimension of, e.g., 256 (which can be adjusted and corresponds to the maximum number of events for each object type). A second dimension is used to select pairs of (action, tag), such as {(1, block), (1, RF event), . . . , (2, block), (2, RF event), . . . , (3, <duration>), (3, <RF>), . . . , (8)}. The action numbers correspond to the 8 types of actions mentioned earlier, and the final dimension of the action space denotes the action step, i.e., the value of an increasing or decreasing step. Other formats for the parameterization may be used.

The action space dimensionality may increase significantly for the shape object if every sample is optimized, as the ID of each sample is encoded in an additional dimension of the action space alongside the shape ID. One way to reduce this dimensionality is to utilize a dictionary of fixed shapes instead. Alternatively, fixing the other optimization parameters and training a separate RL agent solely for optimizing shapes may also help mitigate the growth in dimensionality. These two optimization techniques could be applied alternatively in a coordinate descent strategy.

In act 220, the processor performs reinforcement learning to train the agent. As shown in FIG. 3, the reinforcement learning uses the MR simulator 318 and MR reconstruction 320 in the environment 310 to train from various states provided by the MRI scanner description 312, the object description 314, and MRI sequence description 316. Simulation of MR scanning of an object of the object description 314 using the MRI sequence description 316 by the MR scanner of the MRI scanner description 312 provides a state. Many different states may be provided by different combinations of the virtual objects, MR scanners, and MRI pulse sequences. The agent 175 is machine trained to act to change the MRI sequence descriptor 316 to optimize the MR pulse sequence for each or many possible combinations in the environment 310. The reinforcement learning simulates different MR pulse sequences, different MR scanners, and different virtual objects of the state space in different combinations where the MR pulse sequence descriptor 316 of each combination is optimized in the action space.

The image processor applies deep reinforcement machine learning. The machine learns from the training data (simulations). The broad range of multiple examples or combinations of the environment is used to learn. The action space of the agent, the state of the agent, and the reward function are employed to train the RL agent to optimize the MR sequence.

The learning is deep reinforcement learning. Deep learning uses a neural network. The reinforcement learning learns to decide next acts in the action space defining the MR pulse sequence. Any architecture or layer structure for the deep reinforcement learning may be used. Training is carried out on a dataset of phantom objects and simulated scanners, with the RL agent policy being updated using an RL algorithm like Proximal Policy Optimization Algorithms (PPO), Advantage Actor-Critic (A2C/A3C), Deep Deterministic Policy Gradient (DDPG), Trust Region Policy Optimization (TRPO), Soft Actor-Critic (SAC), Deep Q-Network (DQN), or REINFORCE.

The simulation provides training data. Since the training is to adapt to variance in the environment, the training data includes many combinations or states. The simulation provides many examples that may result from different MR scanners, objects, and MR pulse sequences. The MR sequence is simulated using the MR simulator 318 that mimics the behavior of the specified scanner, with a virtual or phantom object, and the sequence is evaluated either on a tissue map reconstruction task, which can involve producing a set of tissue maps such as T1, T2, and PD maps, or a target task such as organ segmentation. It is also possible to combine both tasks together.

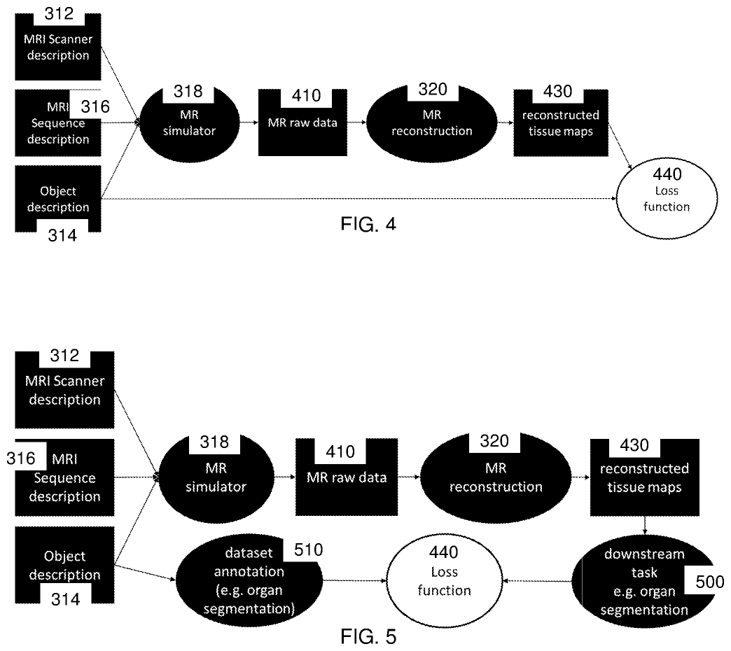

FIGS. 4 and 5 show example simulations using the environment of the state space. The MR simulator 318 uses the current state of the MRI scanner description 312 (e.g., currently selected MR scanner characteristics), the object descriptor 314 (e.g., currently selected virtual object to be scanned), and the MRI sequence descriptor 316 (e.g., currently established MR pulse sequence) to create MR raw data 410 (e.g., k-space data). The simulation reconstructs with the MR reconstruction 320. The reconstruction may be fixed or may form part of the environment 310 which may be altered in state space for training. The reconstruction provides reconstructed tissue maps 430 (e.g., images). In FIG. 4, the end goal or task is the tissue maps 430, so a loss function 440 determines a difference between the simulated tissue map 430 and ground truth. In FIG. 5, the end goal is annotation of the tissue map, so this downstream task 500 is performed on the simulation-created tissue map 430. The loss function 440 compares the annotation (output of the downstream task) with a ground truth provided from the dataset annotation 510 (i.e., from the object description 314 defining the virtual annotation (e.g., segmentation)). The loss from the loss function 440 is used to reward the agent 175. The agent uses the reward to learn values of the learnable parameters of the agent 175 for better selecting changes to the MRI sequence description 316 in the reinforcement learning.

The training data includes ground truth information. Since simulation is used, the ground truth for the annotation is provided by the object description. For example, an organ or tumor boundary is known from the object description 314. The ground truth for the tissue maps 430 is generated by modeling. The loss function 440 may be a combination of losses, such as both the annotation and the tissue maps. The loss function 440 may include other terms, such as a penalty for scan time (e.g., longer scan times are discouraged).

The agent learns to perform actions (e.g., sequence objects) that optimize the MR pulse sequence for a given state. Through a sequence of changes in values for one or more parameters (e.g., objects), the agent alters the MR pulse sequence to optimize MR imaging. The agent learns to optimize for various states.

Values of parameters of one or more (e.g., multiple or all) objects are optimized. The parameters are optimized by finding values resulting in good or sufficient MR imaging for the end task. It is possible to only optimize a subset space of the parameters by constraining the other parameters to stay fixed. For example, the user decides to optimize the list of flip angles (FA) and repetition times (RT). The corresponding objects and variables for FA and RT may be changed by actions of the agent while the other parameters are fixed in value with the constraint masking. Constraints are enforced by masking out actions that are either impossible or violate hard constraints. This can be achieved by assigning a value of infinity to the logits associated with such actions. To compute the objective function, the proposed sequence undergoes MR reconstruction, which can be implemented using an algorithm or network that takes the k-space computed from the MR simulator as input.

The changes or actions may be constrained for parameters that may be altered. The MR pulse sequence is constrained based on input from a user and/or hardware. These constraints limit values of the parameters. For example, an amplitude may be limited, so actions may change the amplitude within the constraint but not beyond the constraint. Similarly, the type of action or sequence object may be limited, such as only allowing certain types of changes for a value of a parameter.

For training the agent, any reward may be used. For example, if the final goal or end task of the MR pulse sequence is reconstruction of a tissue map (see FIG. 4) or annotation (see FIG. 5), then the reward is based on that end task. The reward is greater where the end result of the simulation with the MR pulse sequence minimizes a distance from the ground truth. The optimization of the MR pulse sequence is learned using the loss function based on an end goal of MR imaging. In one embodiment, the optimization uses a loss function based on comparison of (1) reconstructed MR maps from the simulating with (2) a ground truth MR map. Typically, the contrast changes at each time point unless there is a constraint in the MR sequence action space preventing it. In such cases, a pre-computed fingerprint dictionary based on a physical model (such as Bloch simulation or pharmacokinetic modeling) can be provided to the reconstruction task, and a MRF algorithm, a network, or another approach can be used to generate the ground truth. The reward function is a weighted sum of 1) a loss function based on the target task (tissue map) and 2) the scan time which is to be as short as possible. In the case where the end-task is a reconstruction case (tissue map), the loss includes errors (e.g. L1 and/or L2 norm error) on any combination of tissue maps such as T1 map, T2 map, and/or PD map.

Even where T1, T2, and PD maps are the end task, it is possible to reconstruct any contrast image based on these tissue parameters. One approach is to use a dictionary of magnetisation response to convert the tissue parameters in contrasts at different echo times. Another solution is to use a trained neural network to convert the tissue maps to a specific contrast.

In another embodiment, the optimization uses a loss function based on comparison of (1) segmentation from the simulating with (2) a ground truth segmentation from the virtual object. Where the target task is a different task than reconstruction, e.g. an organ segmentation task, detection task, or classification task, the loss on this target task is used instead or as well. For the reconstruction, the model can either be a single network from the MR sequence to the target task, or decomposed in two modules: an intermediate reconstruction, and a target task module (e.g. image segmentation).

The reward may be determined as the loss or from the loss of the loss function 440. A combination of reconstruction (tissue map) and annotation end tasks may be used. This combined loss as the reward may be used to enable few-shot adaptation to new scenarios using a multi-objective RL approach (MORL). The reward and corresponding loss function may include multiple criteria, such as rewarding for multiple end tasks (e.g., tissue map reconstruction and segmentation or segmentation and classification). In one approach, the reward and corresponding loss function includes reward for minimization of or penalty for the length of the MR pulse sequence. Other reward functions may be used.

In one embodiment, the reward dampens over iterations. For example, the reward exponentially dampens over time to incentivize fast convergence or limited number of actions. Any amount of exponential damping may be used. Linear or non-linear reward changes may be used. The training maximizes the sum of the discounted or dampened rewards over time.

To improve the optimization process, a multiresolution approach may be employed. Coarser action steps (e.g., amount of change) and/or lower resolution images/maps of the state at the beginning of the training or inference are used. For later actions in the sequence, finer actions steps or resolution are used, such as gradually increasing resolution towards the end. During training, different agents can be trained at various scales or resolutions. Then, during inference, the optimization can first be performed at the coarser scale before proceeding to finer scales. Alternatively, the agent is trained to operate at the different resolutions in sequence. The agent may be trained to select different scales at different times, such as including scale as a sequence object or action in the parameterization.

After training, the agent architecture is represented as a matrix or tensors. The learned convolution kernels, weights, connections, and/or layers of the neural network or networks for the agent are provided. The matrix or tensors represent the trained policy estimation network or agent.

In act 230, the machine-learnt neural network resulting from the machine learning (agent) is stored. The matrix/tensors and the operators or functional blocks of the architecture are saved in memory. The machine-learnt neural network may be stored locally or transferred over a network or by moving the memory to other computers, workstations, and/or MR scanners.

The training uses a variety of simulations so that the trained network may adapt to any environment. When applied to a particular MR scanner and patient, the machine-learnt neural network (agent) is used to provide an optimized MR pulse sequence. The agent infers acts to establish values for the MR pulse sequence parameters. This MR pulse sequence is used to configure the MR scanner to scan the patient. The machine-learnt neural network is stored so that the network may be applied to scans patients. Many copies may be stored at many different locations, but only one copy per location is needed to deal with many different combinations of MR scanners and patients (e.g., body region, patient characteristics, . . . ).

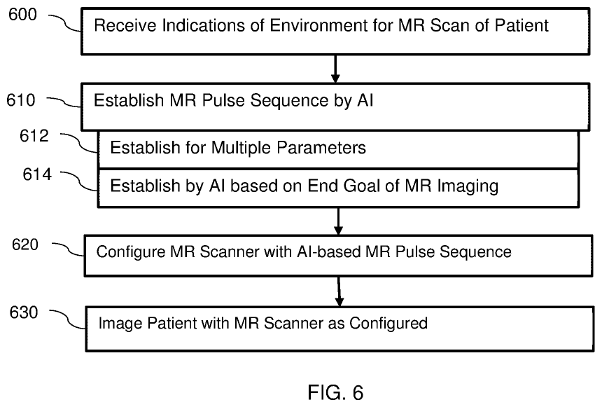

FIG. 6 is a flow chart diagram of one embodiment of a method for establishing a MR pulse sequence for a MR scanner. A RL agent uses the current environment to act pursuant to the learned policy to create the MR pulse sequence. The arrangement of FIG. 3 is used in inference or testing to create an optimized MR pulse sequence. The agent changes the environment by altering the MR pulse sequence, and then repeats input and action based on the change. Through a sequence of actions or iterations, the optimized MR pulses sequence is established.

The method is performed by the system of FIG. 1 or another system. A processor performs acts 600, 610, and 620 to create the MR pulse sequence and configure an MR scanner to scan the patient. An MR scanner is used in act 620 for configuration and act 630 for MR imaging as configured. A display displays one or more end results, such as images of tissue maps as reconstructed and/or rendered with or without annotation (e.g., classification or segmentation). Due to the use of reinforcement learning and/or the trained agent, the patient may be scanned once with a minimized length MR pulse sequence providing good or sufficient end results.

During application of the machine-learned model (agent) to one or more different patients and corresponding different scan data, the same learned weights or values of the machine-learned model are used. The model and values for the learnable parameters of the agent are not changed from one patient to the next, at least over a given time (e.g., weeks, months, or years) or given number of uses (e.g., tens or hundreds). These fixed values and corresponding fixed model are applied sequentially and/or by different processors to scan data for different patients. The model may be updated, such as retrained, or replaced but does not learn new values as part of application for a given patient. In other embodiments, continuous learning is used. Since simulation is used for application, this simulation may also be used to update the agent with on-going reinforcement learning patient-by-patient.

The method is performed in the order shown (top to bottom or numerical) or other orders. For example, acts 612 and 614 are performed together, simultaneously, or in any order. Additional, different, or fewer acts may be provided. For example, a preset, default, or user input settings are used to provide a constraint table. As another example, the results of scanning are stored in a memory (e.g., computerized patient medical record), transmitted over a computer network, and/or displayed on the display.

In act 600, the processor receives indications of an environment for MR scanning of a patient. The medical record for the patient, hospital information system, user input, and/or other sources of information provide or are mined for the environment information for a given scan or appointment.

The processor receives the state information. The indications are values for the current instance for a patient scan. The information to be used by the agent of the reinforcement learned AI in establishing the MR pulse sequence are received. For example, the processor receives a body region of the patient, a size of the body region or the patient, an output task of the MR scanning, and specification of the MR scanner. Additional, different, or less environmental indications may be provided. Information from which specific indications may be derived may be provided. The agent is to use the information (e.g., the body region, size, output task, and specification) in optimizing the MR pulse sequence to be used to scan a particular patient by a particular MR scanner for a particular diagnostic purpose. The information to be used by the agent for this optimization is received.

In one embodiment, during the deployment or testing phase, the user will provide specific details including the scanner model, the object or type of object they wish to scan (which may include a digital twin of the patient), the body region, orientation, and size, as well as the desired task such as T1 or T2 maps reconstruction, or organ segmentation. The user will also specify the sequence parameters they wish to optimize, which may include all the sequence parameters. Any constraints may be specified. The user input is received through a user interface, such as with a keyboard and mouse or trackball. The user may also indicate a proposed or initial MR pulse sequence. A preset or default pulse sequence, such as for the indicated MR scanner to provide the indicated end result, may be used as a starting point.

In act 610, the processor establishes the MR pulse sequence for the environment by reinforcement learned artificial intelligence (RL AI) based on input of the environment including a digital twin of the patient. The RL AI is the trained agent. The agent uses the current state from the indications of the environment to determine a next action for altering the current MR pulse sequence. After a number of iterations, the MR pulse sequence to use for scanning this patient is determined. The agent may indicate no more actions as a stop criterion. Alternatively, the number of iterations is limited to a threshold, an award threshold is applied, or another stop criterion is applied.

In one embodiment, the agent (RL AI) acts to establish the MR pulse sequence without simulation. The indications of the environment including an initial (e.g., default) MR pulse sequence are used by the agent to sequence through acts to alter values of one or more parameters of the MR pulse sequence.

In an alternative embodiment, the agent establishes the MR pulse sequence with simulation. The MR simulator 318 and MR reconstruction 320 with the indications are used to reconstruct tissue maps and/or another end task (e.g., annotation). A digital twin of the patient is used in the simulation without actually scanning the patient. The agent may use loss determined from a ground truth for the simulation as input in selecting the next action. This approach also allows for updating the agent with machine learning based on the current environment.

The processor applies the deep reinforcement machine-learnt network (agent) to change values of the pulse sequence to determine an optimal MR pulse sequence. The agent, as trained, is applied. Any data used by the agent, such as the indications of the environment, are input. For example, scanner model, object, body region, orientation, size, a digital representation of the patient (digital twin), desired end task (e.g., T1 tissue map and segmentation), and any constraints (e.g., what parameters of the MR pulse sequence can be changed and/or limits on the values) are input indications from act 600 used by the agent to establish the MR pulse sequence.

The trained agent is configured by the training to use the received indications to determine actions for establishing the MR pulse sequence. For each iteration of the establishment, one or more actions representing changes to be made are generated. The deep reinforcement machine-learnt network is trained to control the sequence of actions through the iterations based on the learned policy. For example, the actions are determined based on a learned Markov decision process. The current indications are used to determine a probability distribution of settings of parameters of the MR pulse sequence. The distribution provides the settings with greater and lesser probabilities of being rewarded to provide the optimized MR pulse sequence. The action is determined by random or other sampling of the probability distribution. Probability distributions for more than one parameter may be used. The sampling may select which type of action as well as the setting for the action to use. More than one action may be selected, such as altering settings for two or more parameters for a given iteration.

The processor applies the agent of the RL AI in the optimization of the MR pulse sequence. The agent selects a sequence of actions with respect to settings for different objects parameterizing the MR sequence. The optimization to establish the MR pulse sequence through changes uses the RL AI in the environment for the actual scan. A digital twin may be used to avoid multiple scans of the actual patient. The sequence of actions adjusts values of parameters of the MR pulse sequence.

Any number of parameters of the MR pulse sequence may be set. In act 612, multiple (e.g., three or more) parameters of the different parameters defining or parameterizing the MR pulse sequence may be altered by the actions. For example, all the parameters defining the MR pulse sequence may be set (values selected through actions). In other embodiments, only some of the parameters that may be changed are altered. In yet another embodiment, the initial MR pulse sequence is all null values or there are no pulses. This baseline is changed to create the MR pulses sequence.

Where values for only a limited sub-set of the parameters may be altered, then all or a sub-set of those parameters may be altered. For example, the user may indicate that some parameters are to be established and other parameters are to maintain fixed values. The user input, scanning regulations (e.g., from the FDA), and/or hardware capabilities of the MR scanner may constrain the MR pulse sequence. The agent, based on past training and the constraints, may alter all or only some of the parameters that are to be established while maintaining the values of the other parameters constant in the optimization of the MR pulse sequence. The agent, based on past training and the constraints, may alter parameters to values within a constrained range. The agent optimizes without violating the constraints.

In act 614, the RL AI (agent) considers the end goal of the imaging. The end goal may be an input to the agent, so the agent considers the end goal as part of the environment in determining the actions to take. The MR pulse sequence is optimized for the end goal.

In another approach, the end goal determines the loss to use. Where simulation is performed in establishing the MR pulse sequence, the end goal determines the data to compare for loss. For example, the tissue map as simulated with a current MR pulse sequence is compared to a ground truth. The tissue map is the end goal, so the loss is based on the tissue map. In other examples, the end goal is segmentation, multiple tissue maps, detection, and/or classification. The loss may incorporate comparison of data for each of the end goals, thus considering the end goals in determining what changes to make to the MR pulse sequence.

In another approach, the agent or a group of agents determines actions at different resolutions. A sequence of actions is generated. The sequence starts with coarser action (e.g., larger step size in change) and/or a limited set of actions and finishes with finer actions and/or less or not limited set of actions. For example, one agent operates with coarser actions. Another agent operating with finer actions is then applied. Any number of scales or resolutions may be used. Multi-scale may additionally or alternatively use different resolution in the generated output (maps or annotation) and/or input environment.

In act 620, the processor configures the MR scanner with the MR pulse sequence. The optimized MR pulse sequence generated by the RL AI is loaded into the MR scanner. The MR scanner is configured to use the MR pulse sequence as established.

In act 630, the MR scanner images the patient. The MR scanner as configured with the MR pulse sequence transmits pulses and receives responses. Based on the configuration of the MR scanner, a pulse sequence is created. The pulse sequence is transmitted from coils into the patient.

The resulting response of tissue is measured by receiving radio frequency signals at the same or different coils. The scanning results in raw measurements as the scan data. A diagnostic output is generated from the raw measurements. The responses are reconstructed to one or more tissue maps and/or used for annotation (e.g., apply a segmentation).

A display (display screen or device) displays the output (e.g., end task information). For example, one or more tissue maps are displayed. As another example, one or more annotations, such as segmentation, detection, or classification, are displayed with or without tissue maps. The display may be at the MR scanner. The display may be as part of a report for the patient, a pop-up, as a laboratory result, or as part of an electronic health record for the patient.

Listed below are various illustrative embodiments.

In illustrative embodiment 1, a method of establishing a magnetic resonance (MR) pulse sequence for a MR scanner is provided. indications of an environment for MR scanning of a patient are received. The MR pulse sequence for the environment is established by reinforcement learned artificial intelligence based on input of the environment and a digital twin of the patient. Establishing the MR pulse sequence includes optimization by the reinforcement learned artificial intelligence of the MR pulse sequence in the environment for the digital twin of the patient. The MR scanner is configured with the MR pulse sequence, and the patient is imaged by the MR scanner as configured with the MR pulse sequence.

Illustrative embodiment 2. The method of illustrative embodiment 1, wherein receiving the indication comprises receiving state information for the environment, the state information used by an agent of the reinforcement learned artificial intelligence in establishing the MR pulse sequence.

Illustrative embodiment 3. The method of any of illustrative embodiments 1 or 2 wherein receiving the indication comprises receiving a body region of the patient, a size of the body region or the patient, an output task of the MR scanning, and specification of the MR scanner, the body region, size, output task, and specification used by an agent of the reinforcement learned artificial intelligence in the optimization.

Illustrative embodiment 4. The method of illustrative embodiments 1-3 wherein establishing comprises an agent of the reinforcement learned artificial intelligence performing the optimization with a sequence of actions to adjust values of parameters of the MR pulse sequence.

Illustrative embodiment 5. The method of illustrative embodiments 1-4 wherein establishing comprises establishing values of multiple different parameters of the MR pulse sequence.

Illustrative embodiment 6. The method of illustrative embodiment 5wherein establishing comprises establishing values of all of the different parameters that can be set in MR scanner for the MR scanning of the patient.

Illustrative embodiment 7. The method of illustrative embodiments 5 or 6 wherein the multiple different parameters are parameters indicated by a user as to be established and other parameters are fixed, wherein establishing comprises establishing the values of the multiple different parameters while maintaining values of the other parameters constant in the optimization.

Illustrative embodiment 8. The method of any of illustrative embodiments 1-7 wherein establishing comprises establishing where at least one of the multiple different parameters is constrained by hardware of the MR scanner and/or input by the user, the optimization establishing values of the multiple different parameters as constrained.

Illustrative embodiment 9. The method of any of illustrative embodiments 1-8 wherein establishing comprises establishing by the reinforcement learned artificial intelligence where the optimization considers an end goal of the imaging, the MR pulse sequence optimized for the end goal.

Illustrative embodiment 10. The method of illustrative embodiment 9 wherein establishing comprises consideration of the end goal as a type of map, segmentation, and/or detection.

Illustrative embodiment 11. The method of any of illustrative embodiments 1-10 wherein establishing comprises applying an agent of the reinforcement learned artificial intelligence in the optimization where the agent selects a sequence of actions with respect to settings for different objects parameterizing the MR sequence.

Illustrative embodiment 12. The method of any of illustrative embodiments 1-11 wherein establishing comprises establishing over a sequence of different resolutions in actions steps from coarser to finer.

Illustrative embodiment 13. A method for reinforcement machine learning to establish a magnetic resonance (MR) pulse sequence, the method comprising: defining a state space representing the MR pulse sequence, a MR scanner, and a virtual object to be scanned; parameterizing an action space of the MR pulse sequence with a plurality of objects corresponding to actions changing a characteristic of the MR pulse sequence; reinforcement learning, by a processor, an agent, the reinforcement learning simulating different MR pulse sequences, different MR scanners, and different virtual objects of the state space in different combinations where each combination is optimized in the action space; and storing the agent.

Illustrative embodiment 14. The method of illustrative embodiment 13 wherein reinforcement learning comprises the optimization with a loss function based on an end goal of MR imaging.

Illustrative embodiment 15. The method of illustrative embodiment 14 wherein the optimization uses a loss function based on comparison of reconstructed MR maps from the simulating with a ground truth MR map.

Illustrative embodiment 16. The method of any of illustrative embodiments 14 or 15 wherein the optimization uses a loss function based on comparison of segmentation from the simulating with a ground truth segmentation from the virtual object.

Illustrative embodiment 17. The method of any of illustrative embodiments 13-16 wherein optimization in the action space comprises optimization of parameters of multiple of the objects.

Illustrative embodiment 18. The method of illustrative embodiment 17 wherein defining comprises defining with the MR pulse sequence constrained based on input from a user and/or hardware, constraints limiting values of the parameters.

Illustrative embodiment 19. A magnetic resonance (MR) system comprising: a MR scanner configured by settings of controls to scan a region of a patient, the scan providing scan data; a processor configured by a machine-learned agent to configure the MR scanner, the machine-learned agent using simulation of MR scanning by the MR scanner with different values of the settings through a sequence of simulated actions, the different values optimized by the machine-learned agent where the optimized values are used for the settings of the configuration of the MR scanner.

Illustrative embodiment 20. The MR system of illustrative embodiment 19 wherein the machine-learned agent is configured to establish the values of multiple ones of the settings in the optimization, where the optimization is based on an end task of MR map generation and/or segmentation.

Although the subject matter has been described in terms of exemplary embodiments, it is not limited thereto. Rather, the appended claims should be construed broadly, to include other variants and embodiments, which can be made by those skilled in the art.

What is claimed is:

1. A method of establishing a magnetic resonance (MR) pulse sequence for a MR scanner, the method comprising:
receiving indications of an environment for MR scanning of a patient;
establishing the MR pulse sequence for the environment by reinforcement learned artificial intelligence based on input of the environment and a digital twin of the patient, establishing comprising optimization by the reinforcement learned artificial intelligence of the MR pulse sequence in the environment for the digital twin of the patient;
configuring the MR scanner with the MR pulse sequence; and
imaging the patient by the MR scanner as configured with the MR pulse sequence.

2. The method of claim 1 wherein receiving the indication comprises receiving state information for the environment, the state information used by an agent of the reinforcement learned artificial intelligence in establishing the MR pulse sequence.

3. The method of claim 1 wherein receiving the indication comprises receiving a body region of the patient, a size of the body region of the patient, an output task of the MR scanning, and specification of the MR scanner, the body region, size, output task, and specification used by an agent of the reinforcement learned artificial intelligence in the optimization.

4. The method of claim 1 wherein establishing comprises establishing an agent of the reinforcement learned artificial intelligence performing the optimization with a sequence of actions to adjust values of parameters of the MR pulse sequence.

5. The method of claim 1 wherein establishing comprises establishing values of multiple different parameters of the MR pulse sequence.

6. The method of claim 5 wherein establishing comprises establishing values of all of the different parameters that can be set in MR scanner for the MR scanning of the patient.

7. The method of claim 5 wherein the multiple different parameters are parameters indicated by a user as to be established and other parameters are fixed, wherein establishing comprises establishing the values of the multiple different parameters while maintaining values of the other parameters constant in the optimization.

8. The method of claim 1 wherein establishing comprises establishing where at least one of the multiple different parameters is constrained by hardware of the MR scanner and/or input by the user, the optimization establishing values of the multiple different parameters as constrained.

9. The method of claim 1 wherein establishing comprises establishing by the reinforcement learned artificial intelligence where the optimization considers an end goal of the imaging, the MR pulse sequence optimized for the end goal.

10. The method of claim 9 wherein establishing comprises considering of the end goal as a type of map, segmentation, and/or detection.

11. The method of claim 1 wherein establishing comprises applying an agent of the reinforcement learned artificial intelligence in the optimization where the agent selects a sequence of actions with respect to settings for different objects parameterizing the MR sequence.

12. The method of claim 1 wherein establishing comprises establishing over a sequence of different resolutions in actions steps from coarser to finer.

13. A method for reinforcement machine learning to establish a magnetic resonance (MR) pulse sequence, the method comprising:
defining a state space representing the MR pulse sequence, a MR scanner, and a virtual object to be scanned;
parameterizing an action space of the MR pulse sequence with a plurality of objects corresponding to actions changing a characteristic of the MR pulse sequence;
reinforcement learning, by a processor, an agent, the reinforcement learning simulating different MR pulse sequences, different MR scanners, and different virtual objects of the state space in different combinations where each combination is optimized in the action space; and
storing the agent.

14. The method of claim 13 wherein reinforcement learning comprises the optimization with a loss function based on an end goal of MR imaging.

15. The method of claim 14 wherein the optimization uses a loss function based on comparison of reconstructed MR maps from the simulating with a ground truth MR map.

16. The method of claim 14 wherein the optimization uses a loss function based on comparison of segmentation from the simulating with a ground truth segmentation from the virtual object.

17. The method of claim 13 wherein optimization in the action space comprises optimization of parameters of multiple of the objects.

18. The method of claim 17 wherein defining comprises defining with the MR pulse sequence constrained based on input from a user and/or hardware, constraints limiting values of the parameters.

19. A magnetic resonance (MR) system comprising:
a MR scanner configured by settings of controls to scan a region of a patient, the scan providing scan data;
a processor configured by a machine-learned agent to configure the MR scanner, the machine-learned agent using simulation of MR scanning by the MR scanner with different values of the settings through a sequence of simulated actions, the different values optimized by the machine-learned agent where the optimized values are used for the settings of the configuration of the MR scanner.

20. The MR system of claim 19 wherein the machine-learned agent is configured to establish the values of multiple ones of the settings in the optimization, where the optimization is based on an end task of MR map generation and/or segmentation.
